(19) United States
(12) Patent Application Publication
(10) Pub. No.: US 2025/0219663 A1
(43) Pub. Date: Jul. 3, 2025

(54) Single-supply apparatus for signal transmission

(71) Applicant: CLOSED-UP JOINT-STOCK COMPANY DRIVE, Novosibirsk (RU)

(72) Inventor: Yuriy I. Romanov, Novosibirsk (RU)

(21) Appl. No.: 18/662,166

(22) PCT Filed: Aug. 15, 2022
(86) PCT No.: PCT/RU2022/000256

§ 371 Date: May 13, 2024

(51) Int. Cl. H04B 1/04

(52) U.S. Cl. CPC H04B 1/04

(57) ABSTRACT

A single-supply apparatus for signal transmission comprises two operational amplifiers (OA), two transistors, a resistor, a feedback circuit (FC), and a current setter. An output of the first OA is connected to a first electrode of the first transistor, a first input of the first OA is connected to a terminal for receiving an input signal. The second transistor, second OA, and resistor form a current stabilizer (CS). A junction point of the CS input, a third electrode of the first transistor, and a FC first terminal is reserved for connecting a load. A second terminal of the FC is connected to a second input of the first OA. When made as an IC, the apparatus can have the FC and current setter outside elements. Using single-supply operation, the invention ensures widening the dynamic range of the transmitted signals and high growth rate of the output signal.

### BACKGROUND OF THE INVENTION

### Field of the invention

The present invention relates to radio engineering, electronics and measuring technology and is designed for undistorted transmission of wideband signals in miscellaneous electronic systems with single supply operation.

### Description of related art

Unlike well-known apparatus for signal transmission using bipolar supply, obtaining output voltage close to zero turns out to be challenging for single-supply apparatuses. For example, if a pedestal is added to output voltage to offset same closer to zero, then a need arises to accurately control a preset level of the pedestal, particularly with the transmission of small signals that may have amplitude of about several millivolt. That said, diminishing supply voltage (especially for mobile devices), which is the primary trend in the above-mentioned fields, results in a dire need of lowering minimal non-distorted output voltage to keep or widen the dynamic range of the transmitted signals.

That is why the problem of having minimal (“near-zero”) output voltage in single supply apparatus for signal transmission is one of pressing issues of modem electronics, particularly in designing analog and analog-digital chips. Also, it is important for any apparatus for signal transmission, including those with single supply operation, to provide a high growth rate of a signal necessary for undistorted transmission of wideband signals.

Known in the art has been a single-supply operational amplifier (OA) for transmitting a signal disclosed in the Texas Instruments' operational amplifier OPA189 specification (/datasheets/OPAx189 Precision, Lowest-Noise, 36-V, Zero-Drift, 14-MHz, MUX-Friendly, Rail-to-Rail Output Operational Amplifiers datasheet (SBOS830I—September 2017—revised October 2021). The disclosure shows a series connection of an OA input circuit, designed to operate in an input voltage range from −0.1V to the power voltage decreased by 2.5V, and three amplifying modules providing transmission gain of 170 dB with an open feedback circuit. Since the output voltage in the prior art design depends on the load resistance, it lies between 20 mV (at the load resistance of 10 KOhm) and 80 mV (at the load resistance of 2 KOhm). In some cases, this would be unacceptably large and result in distortion of a near-zero transmitted signal. The inability to provide a near-zero output voltage, i.e., proportional to the transmitted signal, is considered a drawback of that design.

Also known has been a similar design disclosed in “Output stage for near rail operation” (U.S. Pat. No. 9,548,707 of Jan. 17, 2017). This design circuitry for non-distorted transmission of low-voltage signals under single supply comprises a differential amplifier with a non-inverting (“+”) and inverting (“−”) inputs, a main transistor arranged in a common emitter configuration, a current generator, a buffer transistor, and an output current circuit. In the circuitry, the output of the differential amplifier is connected to the control electrode of the main transistor, the current generator is connected to one of the electrodes of the main transistor and to the control electrode of the buffer transistor, whereas the buffer transistor's emitter is connected to the input of the output current circuit and represents the output of the design.

The demerit of this design is that the output voltage thereof cannot be less 2 mV when implemented (col. 3, lines 63-65 of the patent). In practice, this is not enough to reach a near zero output voltage and, thus, undistorted transmission of low-voltage signals.

Another analog is a technical decision described in an “Output stage bleeder circuit applied to ultralow quiescent current LDO” (Chinese application 111930167 of Nov. 13, 2020). The design circuitry comprises operational amplifier OA with a non-inverting (“+”) input and an inverting (“−”) input which is an input of the design, a transistor, the gate thereof being connected to an output of the OA and the source thereof being an output of the design, a resistive divider connected between the output of the design and a current source made as a current mirror, and a current controller I_{b}, the midpoint of the divider being connected to the non-inverting “+” input of the OA.

The downside of this design is that it cannot provide both the “near-zero” output voltage and high growth rate of the signal.

The analog believed the closest to the claimed design is a “Rail-to-rail input/output operational amplifier and method” disclosed in U.S. Pat. No. 6,356,153 of Mar. 12, 2002. This apparatus comprises an input stage, two gain boost amplifiers, and an output stage. Essential for achieving the goals of the proposed apparatus is the part of the prior art design having two amplifiers and output stage. This part chosen as a prototype comprises two OAs, four transistors, two resistors and a class AB operation circuit.

In the circuitry, a first terminal of the first transistor is connected to an output of the first OA, and a second terminal of the first transistor is connected to a first terminal of the class AB operation circuit and to a first terminal of the third transistor. A first input of the first OA is to be connected to a source of the signal, a third terminal of the first transistor is connected to another input of the first OA and to a first terminal of the first resistor, and a third terminal of the third transistor is connected to a second terminal of the first resistor. Additionally, a first terminal of the second transistor is connected to an output of the second OA, a second terminal of the second transistor is connected to a second terminal of the class AB operation circuit and to a first terminal of the fourth transistor, a third terminal of the second transistor is connected to an input of the second OA and to a first terminal of the second resistor, a third terminal of the fourth transistor is connected to a second terminal of the second resistor, another input of the second OA is to be connected to the source of the signal, and second terminals of the third and fourth transistors are connected to each other. Common features of the proposed design and prototype are two OAs, two transistors and a resistor, the first terminal of the first transistor being connected to the output of the first OA, the first input of the first OA being for connection to the source of the signal, the first terminal of the second transistor being connected to the output of the second OA, the third terminal of the second transistor being connected to one of the inputs of the second OA and to the first terminal of the resistor,

The prototype operates using class AB amplifying state which tends to have nonlinear distortions of the signal. For that reason, the prototype cannot provide undistorted transmission of signals, particularly wideband “near-zero” signals.

### SUMMARY OF THE INVENTION

The object of claimed invention is overcoming the drawbacks of the prior art and providing a single supply apparatus for signal transmission for undistorted signal transmission in a wide dynamic range which would be able to produce a minimal (“near-zero”) output voltage (of fractions of mV) when a wideband “near-zero” signal is suppled to an input thereof.

The technical result, which the prior art designs are unable to attain, is to substantially widen the dynamic range of a single supply apparatus for signal transmission, providing at the same time a high growth rate of the output signal.

The above technical result is achieved by providing a feedback circuit and output current setter in the apparatus comprising two OAs, two transistors and the resistor with above-described connections thereof, a third terminal of the first transistor being connected to a second terminal of the second transistor, the connection being connected to a load and to the feedback circuit, the feedback circuit being also connected to a second input of the first OA, the output current setter being also connected to the second input of the second OA. The above connections of the elements of the claimed apparatus make it possible to define a current stabilizer therein comprising a second OA, a second transistor and a resistor along with their connections. That said, the output of the output current setter is an input of the current stabilizer, and the output of the current stabilizer is the second terminal of the resistor.

The claimed apparatus has a simpler design as compared with the prototype and can produce a minimal (“near-zero”) output voltage (of fractions of m V versus units and tens of millivolts in prior art). At the same time, a high growth rate of the output signal is achieved which is necessary for undistorted transmission of wideband signals, and nonlinear distortions are eliminated due to using class A amplifying state. This results in the substantial widening of the dynamic range of single-supply apparatuses for wideband signal transmission.

Also presented for patent protection is the claimed technical solution made as an integral circuit (IC) which combines a number of elements of the claimed apparatus. In this embodiment, the above-mentioned technical result is achieved by providing an IC comprising a complex of elements of the apparatus, namely, two OAs, two transistors and a resistor. The output of the first OA is connected to the first terminal of the first transistor, the output of the second OA is connected to the first terminal of the second transistor. The second input of the first OA is connected to the IC terminal intended for supplying an input signal. The third terminal of the second transistor is connected to the first input of the second OA and to a terminal of the resistor. The third terminal of the first transistor is connected to the second terminal of the second transistor, and this connection is connected to the IC terminal intended for connecting to the load and to the first terminal of the feedback circuit, the circuit being external to the IC. Additionally, the IC is provided with a terminal intended for connecting to a second terminal of the external feedback circuit, the above IC terminal being connected to the second input of the first OA and being able to be used for connecting to a source of a second input signal. Also, the integral circuit is provided with a terminal connected to the second input of the second OA and intended for connecting to an external current setter.

### BRIEF DESCRIPTION OF THE DRAWINGS

The claimed invention is explained further using accompanying drawings which present the implementations of the apparatus for signal transmission and where:

FIG. 1 shows the prototype.

FIG. 2a illustrates the claimed invention as compared with the prototype.

FIG. 2b presents the claimed invention made as an IC.

FIG. 3 shows the claimed invention in one of the implementations thereof.

FIG. 4 shows the claimed invention in another implementation thereof.

FIG. 5 is the claimed invention in one more implementation thereof.

FIG. 6 illustrates an embodiment of an output current setter for a current stabilizer in the claimed invention.

FIG. 7 shows another embodiment of an output setter for a current stabilizer in the claimed invention.

FIG. 8 presents one more embodiment of an output setter for a current stabilizer in the claimed invention.

FIGS. 9a-9f show charts illustrating the lowering of the transmitted signal distortion level when using the proposed technical solution; and

FIG. 10 presents a screenshot from an oscillograph screen, illustrating the results of an experiment verifying the achievement of the stated technical result.

### DETAILED DESCRIPTION OF THE INVENTION

With reference to the drawings, the claimed apparatus and operation thereof are explained below.

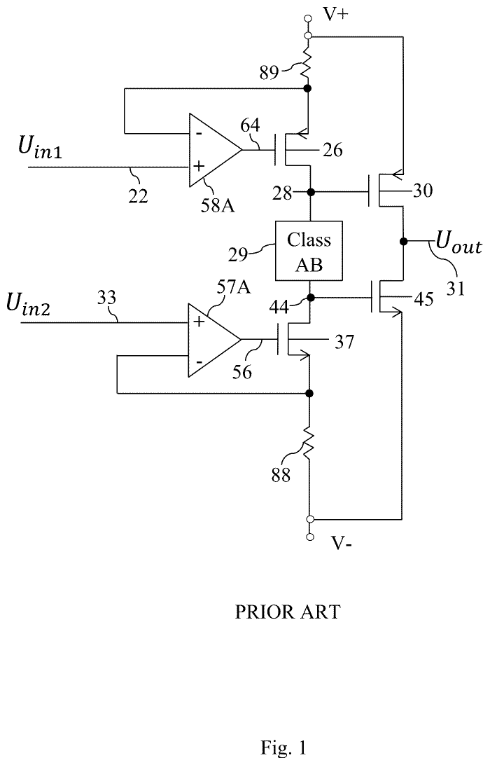

FIG. 1 presents a portion of a prior art rail-to-rail differential amplifier according to U.S. Pat. No. 6,356,153. The portion (prototype) comprises two OAs (58A and 57A), four transistors (26, 30, 37, and 45), two resistors (89, 88), and a class AB operation circuit (29), the prototype having two inputs (22, 33) connected to inputs of the first and second OA, respectively, a point (31) of the connection of third terminals of the third and fourth transistors being an output of the prototype.

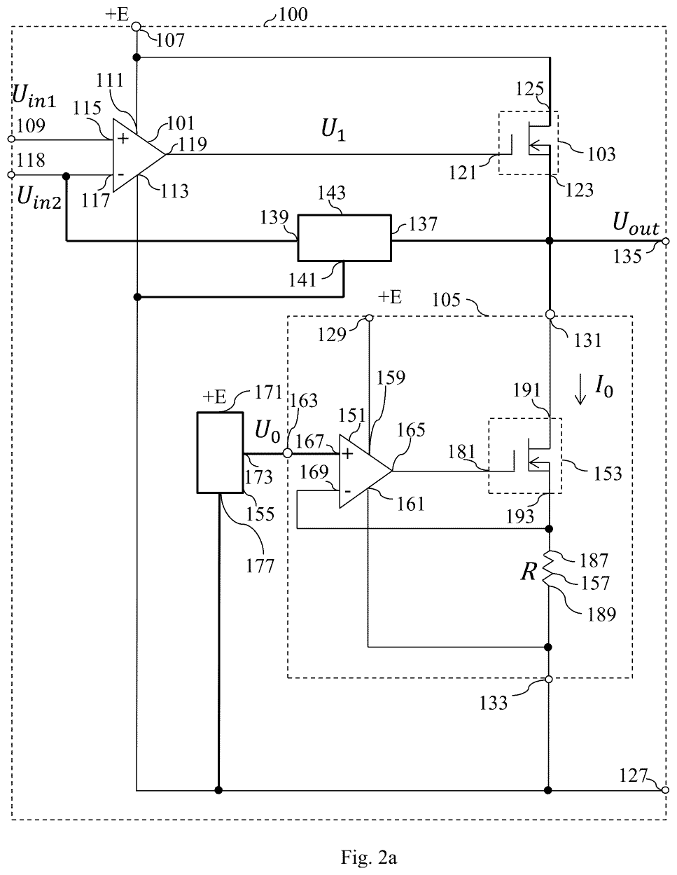

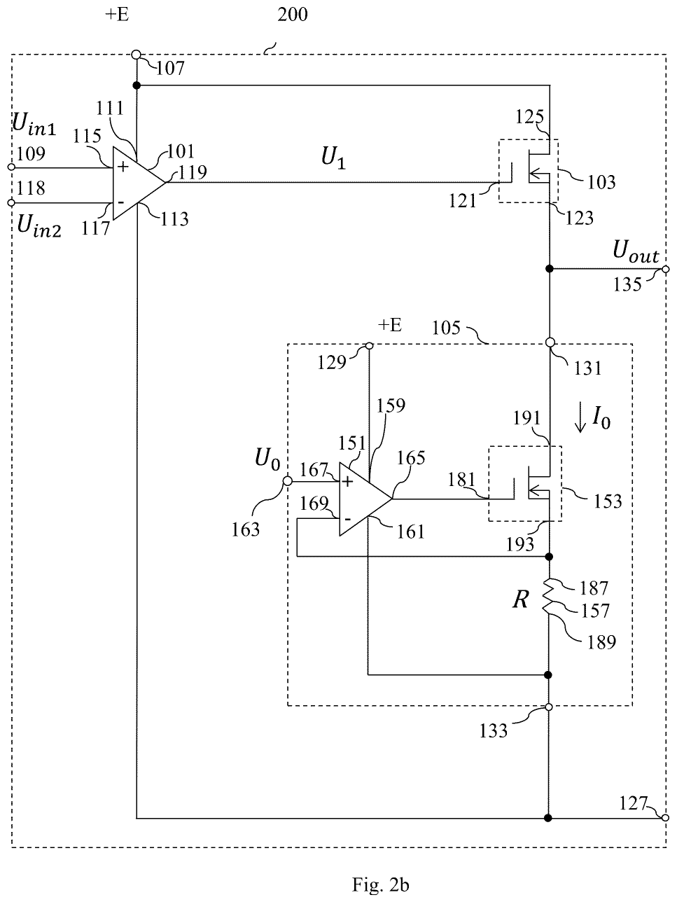

The present invention in comparison to the prototype is shown in FIG. 2a. There, the claimed apparatus 100 comprises a first OA 101, a first transistor (MOSFET in FIG. 2) 103, an output current setter 155, a terminal 107 for connecting to a power supply (PS) positive pole, a first input terminal 109, a first, 111, and a second, 113, PS terminals of the first OA 101, a first input 115 (shown in FIG. 2a as a non-inverting “+” one) of the first OA 101 connected to the first input terminal 109, a second input 117 (shown in FIG. 2a as an inverting one) of the first OA 101 connected to a second input terminal 118, an output 119 of the first OA 101 is connected to a first (control) terminal 121 (gate terminal in FIG. 2a) of the first transistor 103. A second terminal 125 (drain terminal in FIG. 2a) of the first transistor 103 is connected with the first PS terminal 111 of the first OA 101 and with the terminal 107, whereas the second PS terminal 113 of the first OA 101 is connected to a terminal 127 serving for the connection to the common wire (ground) and the negative pole of the PS. A connection of a third terminal 123 (source terminal in FIG. 2a) of the first transistor 103 to a second terminal 191 (drain terminal in FIG. 2a) of a second transistor 153 (MOSFET in FIG. 2a) is used for connecting to a load (not shown) via a terminal 135. A third terminal 193 (source terminal in FIG. 2a) of the second transistor 153 is connected to a first input 169 (an inverting (“−”) one in FIG. 2a) of a second OA 151 and to a first terminal 187 of a resistor 157. A first (control) terminal 181 (gate terminal in FIG. 2a) of the second transistor 153 is connected to an output 165 of the second OA 151. A first PS terminal 159 of the second OA 151 is connected to a contact 129 serving for the connection with a positive pole of the PS, whereas a second PS terminal 161 of the second OA 151 and the second terminal 189 of the resistor 157 are connected to the terminal 127 of the apparatus 100 intended to be connected to the common wire (frame) and the negative pole of the PS. A first terminal 137 of a feedback circuit (FC) 143 is connected to the connection of the first, 103, and second, 153, transistors, a second terminal 139 of the FC 143 is connected to the second input 117 of the first OA 101, whereas a third terminal 141 of the FC 143 is connected to the terminal 127 of the apparatus 100.

It was noted above that the second OA 151, the second transistor 153, and the resistor 157 with the connections between them form a current stabilizer 105 with an input 131 connected to the second terminal 191 of the second transistor 153 and to the terminal 135 of the apparatus 100. Contact 133 connected to a second terminal 189 of the resistor 157 and to the terminal 127 serves an output of the stabilizer 105. A potential controlling the value of the current of the stabilizer 105 is supplied from a second terminal 173 of the output current setter 155 through a contact 163 of the stabilizer 105 to a second input 167 (a non-inverting (“+”) one in FIG. 2a) of the second OA 151. Contact 171 of the output current setter 155, as well as the contact 129 of the stabilizer are to be connected to the positive pole of the PS, while a terminal 177 of the output current setter 155 is connected to the terminal 127. Not shown in FIG. 2a are the PS, an input signal source and the load to be connected to respective terminals of the apparatus.

For clarity, FIG. 2a uses thickened lines to show elements (the FC 143 and output current setter 155) and connections absent in the prototype. It is due to providing those elements and connections that the above-stated technical effect was achieved.

Schematics of the claimed apparatus made as an IC are presented in FIG. 2b. Apparatus 200 comprises first OA 101, first transistor 103 (a MOSFET in FIG. 2b), and current stabilizer 105 implemented identically to that in FIG. 2a. Also, the apparatus 200 has terminal 107 for the connection to the positive pole of the PS, terminal 135 for the connection to the load and to external FC, terminal 127 for the connection to the negative pole of the PS, a first input terminal 109 for the connection to a signal source, a second input terminal 118 to connect to the external PC and another signal source, and terminal 163 to connect to a current setter output. The first input 115 (a non-inverting (“+”) one in FIG. 2b) of the first OA101 is connected to the first input terminal 109 of the apparatus 200, the second input 117 (an inverting (“−”) one in FIG. 2b) of the first OA101 is connected to the second input terminal 118 of the apparatus 200, a first (control) terminal 121 (gate terminal in FIG. 2b) of the first transistor 103 is connected to the output 119 of the first OA 101. A second terminal 125 (drain terminal in FIG. 2b) of the first transistor 103 is connected to a first power supply terminal 1 1 1 of the first OA 101 and to terminal 107 to be connected to the positive pole of the power supply. A second PS terminal 113 of the OA 101 is connected to terminal 127 of the apparatus 200. A point of connection of a third terminal 123 (source terminal in FIG. 2b) of the first transistor 103 and a first terminal 131 of the current stabilizer 105 is connected to terminal 135 of the apparatus 200. An output 133 of the current stabilizer 105 is connected to terminal 127 of the apparatus 200 intended to be connected with the negative pole of the PS. Contact 129 of the current stabilizer 105 is intended to be connected with the positive pole of the PS. Not shown in FIG. 2b, and to be connected to respective terminals of the integral circuit 200, are the PS, an input signal source, the load, the PC, and the output current setter along with connections thereof.

The schematics of one of the embodiments of the claimed apparatus is presented in FIG. 3 where the apparatus 100 is shown comprising OA 101, transistor 103, current stabilizer 105, output current setter 155, and FC 143. Designated 107 is the terminal for connecting to the positive pole of the PS. Also shown in FIG. 3 and related to the OA 101 are the first input terminal 109 of the apparatus, the first PS terminal 111, the second PS terminal 113, the first (non-inverting (“+”) in FIG. 3) input 115, which is connected to the first input terminal 109, the second (inverting (“−”) in FIG. 3) input 117, and the output terminal 119 connected to the first (control-gate terminal in FIG. 3) terminal 121 of the transistor 103. The third terminal 123 of the transistor 103 (source terminal in FIG. 3) is connected to the first terminal 131 of the current stabilizer 105 and to the terminal 135 of the apparatus 100, reserved for connecting to the load, whereas the second terminal 125 (drain terminal in FIG. 3) of the transistor 103 is connected to the first PS terminal 111 of the OA 101 and to the terminal 107 of the apparatus 100, intended for connecting with the positive pole of the PS. The PS terminal 129 of the current stabilizer 105 is reserved for the connection to the positive pole of the PS source. Additionally, there is provided terminal 127 which is reserved for connecting to the negative pole of the PS source and is connected through the common wire (frame) of the apparatus with the second PS terminal 113 of the OA 101, the second terminal 133 of the current stabilizer 105 and the terminal 177 of the output current setter 155. The terminal 163 of the current stabilizer 105 is connected to the second terminal 173 of the output current setter 155. A regular wire connecting the first, 137, and second, 139, terminals of the FC 143 is used as the FC 143 itself. The first terminal 137 of the FC 143 is connected to the connection of the transistor 103 and the current stabilizer 105, whereas the second terminal 139 of the FC 143 is connected to the second input 117 of the OA 101, and the third, unused, terminal 141 of the FC 143 is connected to the terminal 127 of the apparatus. Contacts 171 and 129 of the output current setter 155 and of the current stabilizer 105, respectively, are reserved for connecting to the positive pole of the PS source. Intended for connecting the load is terminal 135 connected to the first terminal 131 of the current stabilizer 105, to the third terminal 123 of the transistor 103 and to the first terminal 137 of the FC 143. Not shown in FIG. 3, and to be connected to respective terminals of the apparatus, are the PS source, an input signal source, and the load.

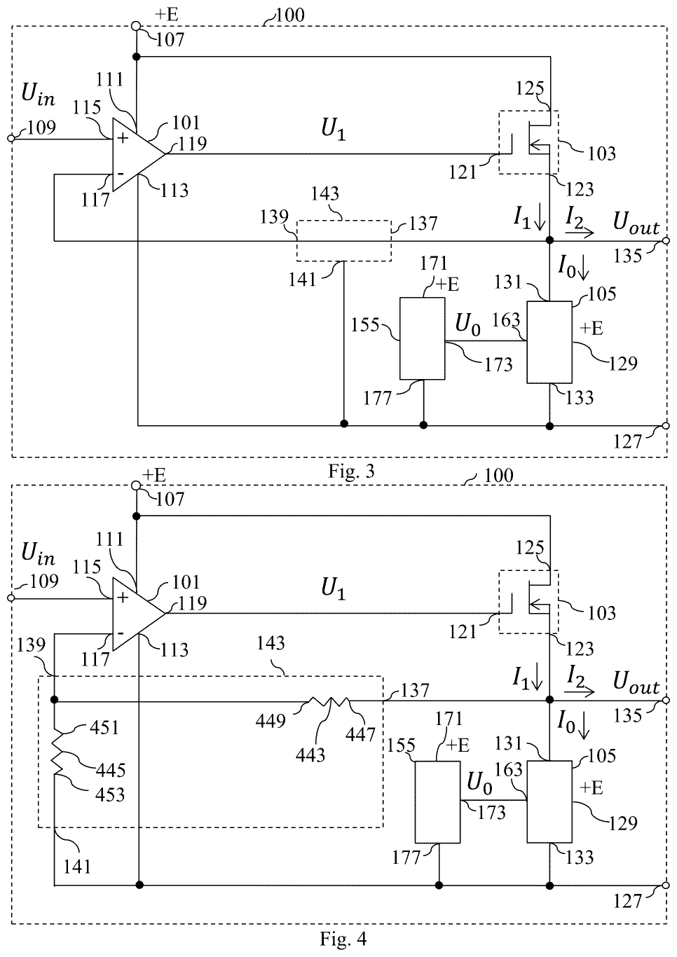

The schematics of another of the embodiments of the claimed apparatus is presented in FIG. 4 where the apparatus 100 is shown comprising OA 101, the transistor 103, the current stabilizer 105, the output current setter 155, and the FC 143. Also depicted are terminal 107 intended for connecting to the positive pole of the PS source, the first input terminal 109 of the apparatus 100, the first (111) and second (113) PS terminals of the OA 101. The OA 101 also has the first (non-inverting (“+”) in FIG. 4) input 115 connected to the first input terminal 109 of the apparatus 100, the second (inverting (“−”) in FIG. 4) input 117, and the output 119 connected to the first (control (gate terminal in FIG. 4)) terminal 121 of the transistor 103. The third terminal 123 of the transistor 103 (source terminal in FIG. 4) is connected to the first terminal 131 of the current stabilizer 105 and to the terminal 135 of the apparatus reserved for connecting to the load, whereas the second terminal 125 (drain terminal in FIG. 4) of the transistor 103 is connected to the first PS terminal 111 of the OA 101 and to the terminal 107 of the apparatus. The terminal 129 of the current stabilizer 105 is also reserved for connecting to the positive pole of the PS source. The terminal 127 is intended for the connection to the negative pole of the PS source and is connected through the common wire (frame) of the apparatus with the second PS terminal 113 of the OA 101, the second terminal 133 of the current stabilizer 105 and the terminal 177 of the output current setter 155. The terminal 163 of the stabilizer 105 is connected to the second terminal 173 of the output current setter 155. Contacts 171 and 129 of the output current setter 155 and of the current stabilizer 105, respectively, are reserved for connecting to the positive pole of the PS source. Also shown in the schematics in FIG. 4 is the FC 143 comprising a first voltage divider of a first, 443, and a second, 445, FC resistors. The first terminal 447 of the first resistor 443 is connected to the first terminal 137 of the FC 143, and the second terminal 449 of the first resistor 443 is connected to the second terminal 139 of the FC 143 and to the first terminal 451 of the second resistor 445. The second terminal 453 of the second resistor 445 is connected to terminal 141 of the FC 143. The first, 137, of three terminals of the FC 143 is connected to the junction point of the transistor 103 and current stabilizer 105, the second terminal 139 is connected to the second input 117 of the OA 101, and the third terminal 141 is connected to the terminal 127 of the apparatus 100. Reserved for connecting to the load is terminal 135 of apparatus 100, connected with the first terminal 131 of the current stabilizer 105, the third terminal 123 of the transistor 103, and the first terminal 137 of the FC 143. Not shown in FIG. 4 and intended to be connected to respective terminals of the apparatus, are the PS source, an input signal source, and the load.

The schematics of a third of the embodiments of the claimed apparatus is presented in FIG. 5 where the apparatus 100 is shown comprising OA 101, the transistor 103, the current stabilizer 105, the output current setter 155, and the FC 143. Also depicted are terminal 107 intended for connecting to the positive pole of the PS source, the first input terminal 109 of the apparatus 100, the first (111) and second (113) PS terminals of the OA 101. The OA 101 also has the first (non-inverting (“+”) in FIG. 5) input 115 connected to the first input terminal 109, the second (inverting (“−”) in FIG. 5) input 117, and the output 119 connected to the first (control (gate terminal in FIG. 5)) terminal 121 of the transistor 103. The third terminal 123 of the transistor 103 (source terminal in FIG. 5) is connected to the first terminal 131 of the current stabilizer 105 and to the terminal 135 of the apparatus reserved for connecting to the load, whereas the second terminal 125 (drain terminal in FIG. 5) of the transistor 103 is connected to the first PS terminal 111 of the OA 101 and to the terminal 107 of the apparatus intended for the connection to the positive pole of the PS source. The terminal 129 of the current stabilizer 105 is also reserved for connecting to the positive pole of the PS source. The terminal 127 is intended for the connection to the negative pole of the PS source. This terminal 127 is also connected through a common wire (frame) of the apparatus with the second PS terminal 113 of the OA 101, the second terminal 133 of the current stabilizer 105, and the terminal 177 of the output current setter 155. The terminal 163 of the stabilizer 105 is connected to the second terminal 173 of the output current setter 155. The terminal 171 of the output current setter 155 and the terminal 129 of the current stabilizer 105 are used for connecting with the positive pole of the PS source. Also shown in the schematics in FIG. 5 is the FC 143 comprising the resistor 443. The first terminal 447 of the resistor 443 is connected to the first terminal 137 of the FC 143, and the second terminal 449 of the resistor 443 is connected to the second terminal 139 of the FC 143. The first, 137, of three terminals of the FC 143 is connected to the junction point of the transistor 103 and current stabilizer 105, the second terminal 139 is connected to the second input 117 of the OA 101, and the third, unused, terminal 141 is connected to the terminal 127 of the apparatus.

Also, as depicted in FIG. 5, the apparatus 100 is provided with the second input terminal 118 and comprises a third, 545, a fourth, 547, and a fifth, 549, resistors, wherein the fourth, 547, and the fifth, 549, resistors, form a second voltage divider. The second input terminal 118 is connected to the first terminal of the third resistor 545, whose second terminal 555 is connected to the second input 117 of the OA 101 and to the second terminal 139 of the FC 143. The first terminal 559 of the fourth resistor 547 is connected to the input 115 of the OA 101, the second terminal 561 of the resistor 547 is connected to the terminal 127 of the apparatus 100. The fifth resistor 549 is connected via the first terminal 563 thereof to the first input terminal 109 and, via the second terminal 565 thereof, to the first input 115 of the OA 101. Not shown in FIG. 5 and intended to be connected to respective terminals of the apparatus, are the PS source, input signal sources, and the load.

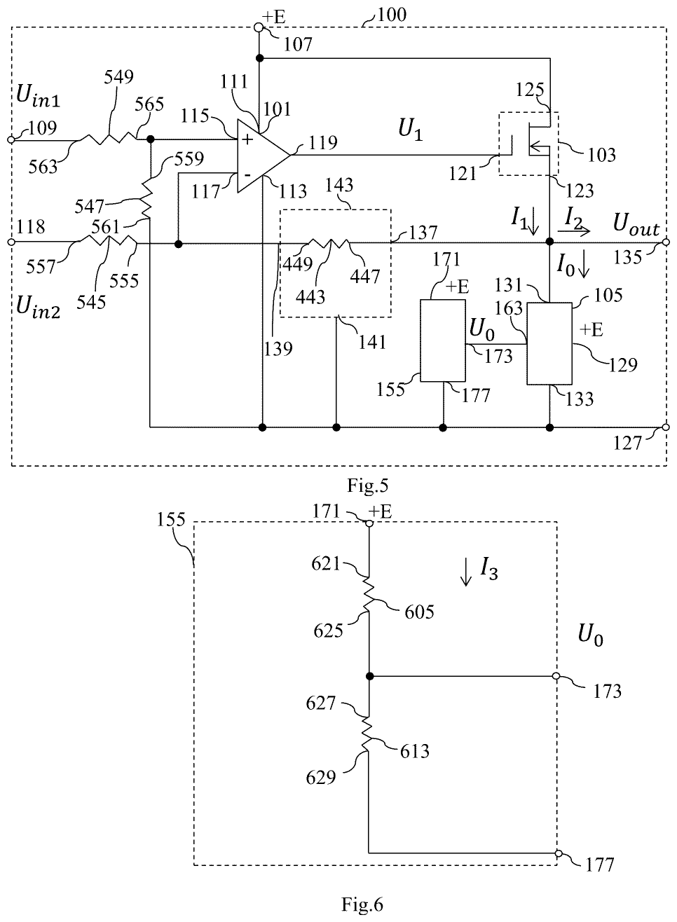

FIG. 6 presents one of possible embodiments of the output current setter 155 where the latter is made as a third voltage divider. This embodiment can be used in any embodiment of the claimed apparatus including, but not limited to, embodiments shown in FIGS. 3-5. Shown in FIG. 6 are: the output current setter 155, a first resistor 605 of the third voltage divider and a second resistor 613 of the third voltage divider. A first terminal 621 of the first resistor 605 is connected to the first terminal 171 of the output current setter 155, intended to be connected to the positive pole of the PS source, a second terminal 629 of the second resistor 613 of the output current setter is connected to the third terminal 177 of the output current setter 155 reserved for connecting with the negative pole of the PS source, whereas a second terminal 625 of the first resistor 605 of the output current setter and a first terminal 627 of the second resistor 613 of the current setter are connected to the second terminal 173 of the output current setter intended to be connected to the current stabilizer 105.

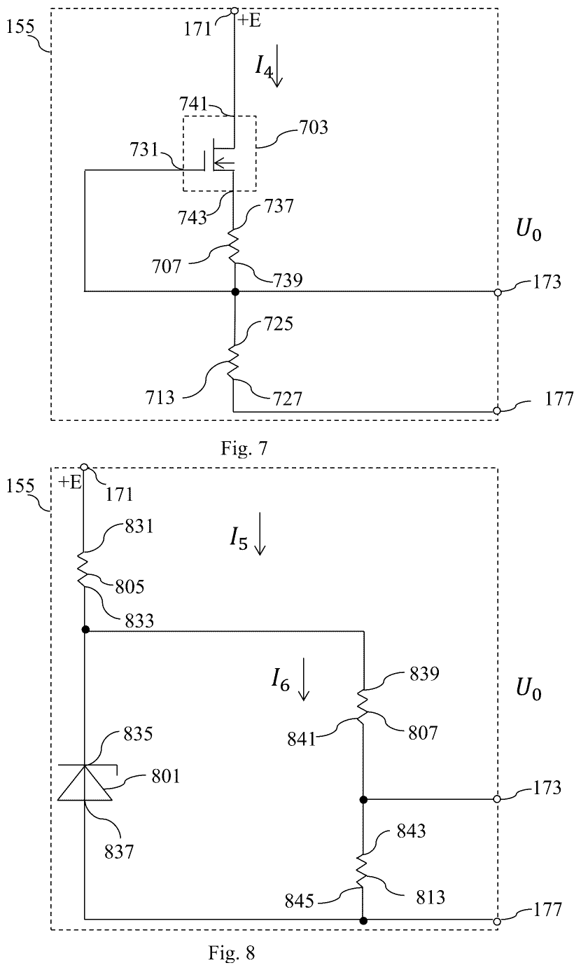

FIG. 7 represents another of possible embodiments of the output current setter 155, using a field-effect transistor (FET) and a fourth voltage divider. This embodiment can be used in any embodiment of the claimed apparatus including, but not limited to, embodiments shown in FIGS., 3-5. Shown in FIG. 7 are: the output current setter 155, a FET 703, a first, 707, and a second, 713, resistors of the output current setter serving as a first and a second elements of the fourth voltage divider. The drain terminal 741 of the FET 703 is connected to the output current setter first terminal 171 intended to be connected to the positive pole of the PS source, the source terminal 743 of the FET 703 is connected to the first terminal 737 of the first resistor 707 of the output current setter, the gate terminal 731 of the FET 703 is connected to the junction point of the second terminal 739 of the first resistor 707 of the output current setter and the first terminal 725 of the second resistor 713 of the output current setter and to the output current setter second terminal 173 intended to be connected to the current stabilizer 105. The second terminal 727 of the second resistor 713 of the output current setter is connected to the output current setter third terminal 177 intended to be connected to the negative pole of the PS source.

FIG. 8 represents one more possible embodiment of the output current setter 155, using a reference voltage source and a fifth voltage divider. This schematic can be used in any embodiment of the claimed apparatus including, but not limited to, embodiments shown in FIGS. 3-5. Shown in FIG. 8 are: the output current setter 155, a reference voltage source 801, a first, 805, a second, 807, and a third, 813, resistors of the output current setter serving a first, a second, and a third elements of the fifth voltage divider. The first terminal 831 of the first resistor 805 of the output current setter is connected to the output current setter first terminal 171 intended to be connected to the positive pole of the PS source, the second terminal 833 of the first resistor 805 is connected to the first terminal 835 of the reference voltage source 801 and to the first terminal 839 of the second resistor 807, the second terminal 841 of the second resistor 807 is connected to the first terminal 843 of the third resistor 813 and to the second terminal 173 of the output current setter 155 intended to be connected to the current stabilizer 105. The second terminal 845 of the third resistor 813 of the output current setter is connected to the second terminal 837 of the reference voltage source 801 and to the output current setter third terminal 177 intended to be connected to the negative pole of the PS source,

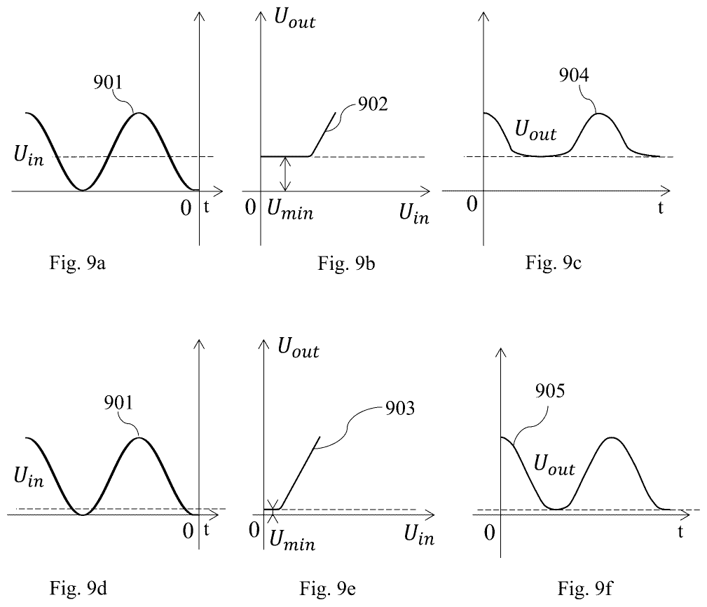

Presented in FIGS. 9a-9f are charts that illustrate the lowering of the level of distortion of the information signal as it is transmitted by the proposed apparatus. Numerated in FIG. 9 are: 901—an input signal, 902—an amplitude response for prior art designs, 903—an amplitude response in the proposed apparatus; 904—an output signal in the prior art designs (distorted), and 905—an output signal in the proposed apparatus.

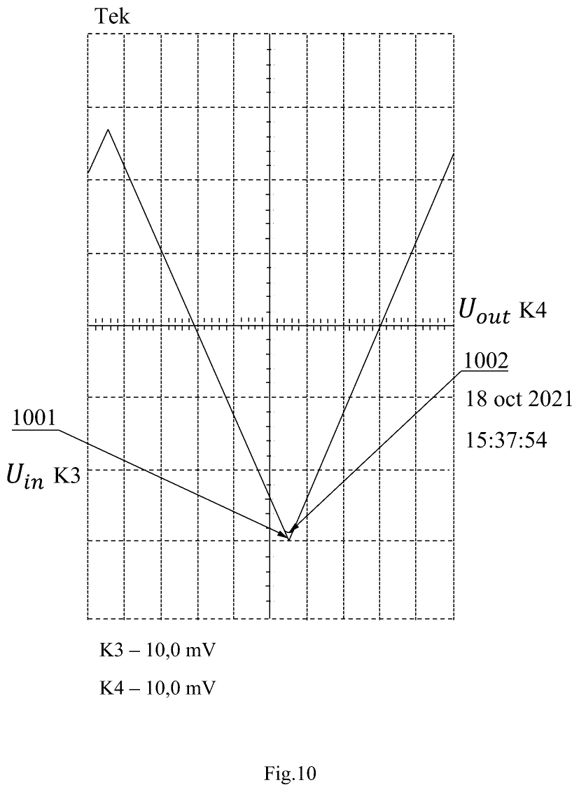

Presented in FIG. 10 are oscillograms of input and output signals of the claimed apparatus that confirm that the claimed technical result was obtained. Designated in the figure are 1001—the oscillogram of an input test voltage and 1002—an oscillogram of the output voltage.

A single-supply apparatus 100 for transmitting signals shown in FIG. 3 is one of the embodiments of the claimed invention which operates in a voltage repeater mode. As an input signal having voltage Uᵢₙ is applied to the terminal 109, reserved for connecting with a source of the input signal, and then to the first, non-inverting (“+”), input 115 of the OA 101, voltage U₁ appears at the output 119 of the OA 101 and comes to the first, control, terminal 121 of the transistor 103 which operates in a linear mode. The current stabilizer 105 generates direct stable current Iₒ, the value thereof depending on voltage U₀ applied from the second terminal 173 of the output current setter 155 to the control input 163 of the current stabilizer 105.

Parameters of the current stabilizer 105 are selected in such a manner as to ensure that the minimal current stabilizer voltage drop (between terminals 131 and 133 thereof), Uₘᵢₙ cs, corresponding to the beginning of the current stabilization mode, be, for example, 0.2 mV (or another value allowing for non-distorted signal transmission).
Flowing of the current lo through the current stabilizer 105 creates between the terminals 131 and 133 thereof output voltage Uₒᵤₜ, which is applied from the terminals 135 and 127 of the apparatus connected to the terminals 131 and 133 to a load (not shown).
Current flowing through the transistor 103 is defined by both current I, of the current stabilizer 105 and load current I₂=Uₒᵤₜ/R where R is load resistance,
If the load is connected between the terminals 135 and 127 of the apparatus, then

$${I}_{1} = {I}_{0} + {U}_{out} / R ; \qquad ( 1 )$$

and it is necessary that this current not exceed the maximum allowed value for the transistor 103. If the load is connected between the terminals 135 and 107 of the apparatus, then

$${I}_{1} = {I}_{0} - {U}_{out} / R \qquad ( 2 )$$

and it is necessary that this current be no less than the value allowing for the linear mode of operation of the transistor 103.
From the first terminal 131 of the current stabilizer 105, the voltage Uₒᵤₜ comes through the FC 143 made as a regular wire to the inverting (“−”) input 117 of the OA 101, thus forming the following strong feedback circuit: the OA 101—the transistor 103—the FC 143-OA 101. If, for some reason, the output voltage Uₒᵤₜ at the inverting (“−”) input 117 of the OA 101 becomes smaller than the Uiₙ value at the non-inverting (“+”) input 115 thereof, then the voltage Ui at the first, control, terminal 121 of the transistor 103 increases and slightly opens the transistor 103, which results in the increasing of the output voltage Uₒᵤₜ of the apparatus. The value of Uₒᵤₜ reaches Uᵢₙ and the relation

$${U}_{out} = {U}_{in} \qquad ( 3 )$$

is thus met.

On the other hand, if the output voltage Uₒᵤₜ at the inverting (“−”) input 117 of the OA 101 exceeds the value Uiₙ at the non-inverting (“+”) input 115 of the OA 101, then the voltage Ui at the first (control) terminal 121 of the transistor 103 decreases and slightly closes the transistor 103, which results in decreasing the output voltage Uₒᵤₜ of the apparatus to reach the level of the Uᵢₙ, and the relation (3) is met again. Consequently, the output voltage Uₒᵤₜ for the schematic of FIG. 3 is always as equal as practically possible to the value of the input voltage Uᵢₙ. The transmission response K of the above apparatus shown in FIG. 3 is equal to one, and, accordingly, it operates as a voltage repeater.

Conventional OA for a single-supply operation, such as OPA189, OPA365 of Texas Instruments, and others, that can be used as the OA 101 in the proposed apparatus, are unable to ensure that the voltage Ui at the output 119 of the OA 101 be less than several tens of millivolts. However, Ui in the proposed apparatus according to FIG. 3 always exceeds the value of Uₒᵤₜ by the amount of the potential difference between the control terminal 121 of the transistor 103 and the third terminal 123 thereof which is connected to the first terminal 131 of the current stabilizer 105. It is just this potential difference that ensures the bias of the output voltage Ui of a conventional OA 101 toward “near-zero” values at the output of the proposed apparatus, thereby contributing to the substantial lowering of the distortion level upon transmitting “near-zero” signals in the single-supply operation which, in turn, facilitates widening the dynamic range of apparatuses for signal transmission that have single-supply (the foregoing is ensured if the gate-source voltage of the transistor 103 exceeds the minimal output voltage of the OA 101, see Uₘᵢₙ in FIG. 9e). Upon increasing the input voltage Uᵢₙ up to several volts (depending on the parameters of a conventional OA 101), the apparatus operates in the same way ensuring the relation (3), the value of Uₒᵤₜ being always less than Ui by the value of the potential difference between the control terminal 121 of the transistor 103 and the third terminal 123 thereof. The apparatus 200 mase as a integral circuit operates similarly, the only difference being that the FC 143 and output current setter 155 can be external relative to the integral circuit and connected to the above-mentioned terminals thereof. Where it is desirable to obtain the transmission response exceeding one, such as 1.5 or 10, or any other practically feasible value (amplifying condition), the FC 143 has to comprise a voltage divider, such as a resistive one.

The schematics of such an embodiment of the claimed apparatus is shown in FIG. 4 (an amplifier circuit). The apparatus 100 in such a case operates as follows. When an input signal of voltage Uᵢₙ is applied to the terminal 109, intended to be connected to an input signal source, and, accordingly, to the first, non-inverting (“+”) input 115 of the OA 101, voltage Ui emerges at the output 119 of the OA 101. The U₁ voltage proceeds to the first, control, terminal 121 of the transistor 103 operating in a linear mode. The current stabilizer 105 generates direct stable current lo, the value thereof depending on voltage U₀ applied from the second terminal 173 of the current setter 155 to the control input 163 of the current stabilizer 105. Parameters of the current stabilizer 105 are selected in such a manner as to ensure that the minimal current stabilizer voltage drop (between terminals 131 and 133 thereof), U_{min cs}, corresponding to the beginning of the current stabilization mode, be, for example, 0.2 mV (or another value allowing for non-distorted signal transmission).

Flowing of the current Io through the current stabilizer 105 creates between the terminals 131 and 133 thereof output voltage Uₒᵤₜ, which is applied from the terminals 135 and 127 of the apparatus connected to the terminals 131 and 133 to a load (not shown). Current flowing through transistor 103 is defined by both current L of the current stabilizer 105 and load current U=Uₒᵤₜ/R where R is load resistance. If the load is connected between the terminals 135 and 127 of the apparatus, then the relation (1) is met, and it is necessary that this current not exceed the maximum allowed value for the transistor 103. If the load is connected between terminals 135 and 107 of the apparatus, then the relation (2) is met, and it is necessary that this current be no less than the value allowing for the linear mode of operation of the transistor 103.

From the first terminal 131 of the current stabilizer 105 and through the FC 143 comprising a first voltage divider (having the first, 443, and second, 445, resistors), the voltage Uₒᵤₜ comes to the inverting (“−”) input 117 of the OA 101. As a result, the following feedback circuit emerges: OA 101—the transistor 103—the PC 143—OA 101. Thus, voltage Uₒᵤₜ*R 445/(R 445+R 443) (4); where R 443, R445—nominal values of resistance of the first, 443, and second, 445, resistors, respectively, ends up applied to the inverting (“−”) input of the OA 101.

If, for some reason, the output voltage Uₒᵤₜ is smaller than the Uᵢₙ value at the first input 115 of the OA 101, then the voltage Ui at the first, control, terminal 121 of the transistor 103 increases and slightly opens the transistor 103, which results in the increasing of the output voltage Uₒᵤₜ of the apparatus. The increased value of Uₒᵤₜ, via the FC 143 comprising the first voltage divider (443, 445), again comes to the second input 117 of the OA 101, and this process occurs until the relation is met:

$${U}_{in} = {U}_{out} / ( 1 + R 443 / R 445 ) . \qquad ( 5 )$$

On the other hand, if the value of the voltage Uₒᵤₜ (1+R443/R445) at the inverting (“−”) input 117 of the OA 101 is larger than the value of Uᵢₙ at the non-inverting (“+”) input 115 thereof, then the voltage Ui at the first, control, terminal 121 of the transistor 103 will be decreasing, thus closing the transistor 103. In response to that, the output voltage Uₒᵤₜ of the apparatus will decrease, and, via the FC 143 comprising the first voltage divider (443, 445), will again be coming to the inverting (“−”) input 117 of the OA 101 until the relation (5) is met again. Therefore, the output voltage Uₒᵤₜ for the schematic of FIG. 4 is nearly always equal to the input signal voltage Uᵢₙ, with the transmission response

$$K = {U}_{out} / {U}_{in} - I + R 443 / R 445 , \qquad ( 6 )$$

In this way, the transmission response exceeding one, for example 1.5 or 10 or any other practically feasible value (depending on the correlation between R443 and R445) is achieved in the embodiment of the proposed apparatus in FIG. 4. Therefore, it serves as an amplifier.

Conventional OAs for single-supply operation (such as OPA 189, OPA 365 of Texas Instruments, and others), which could be used as the OA 101 in the proposed apparatus, are unable to provide the voltage U i of less than several tens of millivolts at the output 119 of the OA 101. Because of that, Ui in the FIG. 4 embodiment of the proposed apparatus is always larger than Uₒᵤₜ by the value of the potential difference between the control terminal 121 of the transistor 103 and the third terminal 123 thereof connected to the first terminal 131 of the current stabilizer 105. It is this potential difference that ensures the bias of the output voltage of the conventional OA 101 toward “near-zero” values at the output of the proposed apparatus, thus contributing to the substantial lowering of the distortion level upon transmitting low voltage signals in the single-supply operation and to widening the dynamic range of such apparatuses for signal transmission. The above is ensured where the gate-source voltage of the transistor 103 exceeds the minimal output voltage of the OA 101 (see Uₘᵢₙ in FIG. 9e).

Upon increasing the input voltage Uᵢₙ up to units of volt (which depends on the parameters of the conventional OA 101), the apparatus operates the same way to ensure that the relation (5) is met, the value Uₒᵤₜ being always less than U₁ by the value of the potential difference between the control terminal 121 of the transistor 103 and the third terminal 123 thereof. The apparatus 200 made as an integral circuit (but with the difference that the FC 143 and output current setter 155 can be external relative to the integral circuit) operates similarly. Where a difference of two voltages is required to be obtained and then amplified, attenuated, or transmitted unchanged (a differential amplification mode), the apparatus will comprise an additional input connected to the inverting input of the OA via an additional resistor, Additionally, the apparatus will comprise a second voltage divider included between the main input of the apparatus and the input of the OA.

A schematic of such a differential amplifier (a third possible implementation of the apparatus) is presented in FIG. 5. Apparatus 100 operates as follows. A first input signal Uᵢₙ₁ is applied to terminal 109 serving for connecting to a first source (not shown) of an input signal. Through a second voltage divider formed by the fifth, 549, and fourth, 547, resistors, the voltage Umi comes to the non-inverting (“+”) input 115 of the OA 101, whereas a second input signal Uᵢₙ 2 comes from the terminal 118 of the apparatus through the third resistor 545 to the inverting (“−”) input 117 of the OA 101. With that, voltage Ui emerges at output 119 of the OA 101 and comes to the first, control, terminal 121 of the transistor 103 which operates in a linear mode. The current stabilizer 105 generates direct stable current Io, the value thereof depending on voltage Uo applied from the second terminal 173 of the output current setter 155 to the control input 163 of the current stabilizer 105. Parameters of the current stabilizer 105 are selected in such a manner as to ensure that the minimal current stabilizer voltage drop (between terminals 131 and 133 thereof), U_{min cs}, corresponding to the beginning of the current stabilization mode, be, for example, equal to 0.2 mV (or to another value allowing for non-distorted signal transmission),

Flowing of the current Iₒ through the current stabilizer 105 creates output voltage Uₒᵤₜ at the terminals 131 and 133 of the latter. From terminals 135 and 127 of the apparatus, which are connected to terminals 131 and 133 of the current stabilizer 105, the voltage Uₒᵤₜ is applied to a load (not shown). Current I₁ flowing through transistor 103 is defined by both the current Io of the current stabilizer 105 and load current I₂=Uₒᵤₜ/R, where R is an active load resistance.

If the load is connected between terminals 135 and 127 of the apparatus, then the relation (1) is met. In this case it is necessary that the value of this current be no more than what is maximum permissible for the transistor 103. If the load is connected between the terminals 135 and 107 of the apparatus, then the relation (2) is met, and it is necessary that the value of this current be no less than that allowing for the linear mode of operation of the transistor 103. At the same time, a portion of the output voltage Uₒᵤₜ through the first resistor 443 of the FC 143 comes to the inverting (“−”) input 1 17 of the OA 101 (wherein the first resistor 443 and the third resistor 545 form a sixth voltage divider). The output voltage Uₒᵤₜ in the schematic of FIG. 5 is correlated with the input voltages Uᵢₙ₁ and Uᵢₙ₂ in accordance with the known relation

$${U}_{out} = α * ( {U}_{in 1} - {U}_{in 2} ) \qquad ( 7 )$$

$$where$$

$$α = R 443 / R 545 = R 547 / R 549 \qquad ( 8 )$$

a differential coefficient of transmission of input voltages, and R443, R545, R547, R549—rated values of resistance of the first, 443, third, 545, fourth, 547, and fifth, 549, resistors, respectively.

As a specific apparatus is implemented according to this embodiment, strict adherence to the relation (8) is optional: the rated values for the first, 443, third, 545, fourth, 547, and fifth, 549, resistors can be chosen based on a particular problem to be solved in the apparatus. Depending on the rated values of resistance of the resistors, the differential coefficient a can be more than one, less than one, or equal to one, making it possible to amplify, or attenuate the difference of the two voltages, or to transmit it unchanged. In this way, the output voltage Uₒᵤₜ is always proportional to the difference Uᵢₙ₁−Uᵢₙ₂ of the input voltages. Additionally, this embodiment makes it possible to amplify, or attenuate the difference of the two voltages under a proper selection of the rated values for the first, 443, third 545, fourth 547, and fifth 549 resistors. Accordingly, it functions as a differential amplifier.

Conventional OAs for single-supply operation (such as OPA 189, OPA 365 of Texas Instruments, and others), which could be used as the OA 401 in the proposed apparatus, are unable to provide the voltage Ui of less than several tens of millivolts at the output 119 of the OA 101. However, U, in the FIG. 5 embodiment of the proposed apparatus is always larger than Uₒᵤₜ by the value of potential difference between the control terminal 121 of the transistor 103 and the third terminal 123 thereof connected to the first terminal 131 of the current generator 105. It is this potential difference that ensures the bias of the output voltage of the conventional OA 101 toward “near-zero” values at the output of the proposed apparatus, thus contributing to the substantial lowering of the distortion level upon transmitting low voltage signals in the single-supply operation and to widening the dynamic range of such apparatuses for signal transmission. The above is ensured where the gate-source voltage of the transistor 103 exceeds the minimal output voltage of the OA 101 (see Uₘᵢₙ in FIG. 9e).

As the input voltages Uᵢₙ₁ and Uᵢₙ₂ increase up to units of volt (depending on the parameters of the conventional OA 101), the circuit operates the same way, ensuring that the relation (7) is met. As this takes place, the value of Uₒᵤₜ is always less than U₁ by the value of the potential difference between the control terminal 121 of the transistor 103 and the third terminal 123 thereof. The apparatus 200 made as an integral circuit (but with the difference that the FC 143 and current setter 155 can be external relative to the integral circuit) operates similarly.

Apart from the embodiments of the proposed design shown in FIGS. 3-5 and described in the above, feasible are also other embodiments of the apparatus differing in connecting various circuits to the inputs and output of the OA, as disclosed, for example, in the specification of the above-mentioned operational amplifier OPA 189.

Further, the operation of the current stabilizer shown in FIG. 2a is described. This structure can be used for all possible implementations of the claimed apparatus, specifically, but with no limitation thereby, for those shown in FIGS. 3-5.

As the output voltage Uₒᵤₜ is present at the terminals 135 and 127 of the proposed apparatus, it appears to be applied to the terminals 131 and 133 of the current stabilizer 105 and is distributed between the second transistor 153, i.e., between the terminals 181 and 193 thereof, and the resistor 157, i.e., between the terminals 187 and 189 thereof. The voltage from the terminal 187 of the resistor 157 comes to the first input 169 of the OA 151 and is compared with the voltage U₀ at the second input 167 of the second OA 151 that comes from the second terminal 173 of the output current setter 155 via the terminal 163 of the current stabilizer 105. If the voltage at the first input 169 of the second OA 151 exceeds the voltage U₀ at the second input 167 thereof, an unbalance signal is formed at the output 165 of the second OA 151. The unbalance signal, applied to the control terminal 181 of the second transistor 153 operating in a linear mode, slightly closes the transistor 153, a current therethrough decreases, and the voltage at the terminal 187 of the resistor 157 and, consequently, at the first input 169 of the second OA 151 becomes equal to the voltage U₀ at the second input 167 thereof. Conversely, if the voltage at the first input 169 of the second OA 151 is lower than the voltage U₀ at the second input 167 thereof, the level of the unbalance signal at the output 165 of the second OA 151 changes. The unbalance signal, coming to the control terminal 181 of the second transistor 153, slightly opens the second transistor 153, a current therethrough increases, and the voltage at the terminal 187 of the resistor 157 and, consequently, at the first input 169 of the second OA 151 again becomes equal to the voltage U₀ at the second input 167 thereof.

In this manner, always met in the current stabilizer 105 made according to FIG. 2a is the relation

$${I}_{0} * {R}_{m} = {U}_{0} \qquad ( 9 )$$

where Rₘ is a rated value of resistance of the resistor 157 and Uₒ—voltage at the second terminal 173 of the output current setter 155.
In other words, always flowing through the current generator 105 is direct current

$${I}_{o} = {U}_{o} / {R}_{m} \qquad ( 10 )$$

whose value is set by voltage U₀ at the output of the output current setter 155 (at the second terminal 173 thereof).
The voltage drop U_{min cs} between the terminals 131 and 133 of the current stabilizer 105 corresponding to the beginning of the current stabilization mode is determined by the relation

$${U}_{min cs} = {I}_{0} * {R}_{cs} \qquad ( 11 )$$

where I₀—direct current of the current stabilizer 105 and R_{cs} is resistance between the terminals 131 and 133 of the current stabilizer 105, and

$${R}_{cs} = {R}_{m} + {R}_{DS ( on )} \qquad ( 12 )$$

where Rₘ—the rated value of resistance of the resistor 157 and R_{DS(on)} is static drain-to-source on-state resistance of the second transistor 153 in the open state thereof.
Properly selecting the rated value R of resistance of the resistor 157 and choosing the second transistor 153 with the required R_{DS(on)}, one can conveniently ensure fulfilling the above formulated relation, so as to provide that the voltage between the terminals 131 and 133 of the current stabilizer 105 corresponding to the beginning of the current stabilization mode be equal to, for example, 0.2 mV (or to another value ensuring non-distorted signal transmission).

To obtain U_{min cs} equal, for example, to 0.2 mV, the value of the drain-to-source channel resistance R_{DS(on)} of the second transistor 153 in open state thereof must amount to several hundred milliohm. With that, parasitic capacitances drain-source and gate-drain of the second transistor 153 can each reach the value of several tens of picofarads, and this interferes with non-distorted transmission of wideband signals. In the claimed apparatus, however, the gate-drain capacitance is short-circuited by the output resistance of the second OA 151, whereas the effect of the drain-source capacitance is neutralized by the feedback circuit from the source terminal 193 of the second transistor 153 via the first input 169 of the second OA 151 and the output 165 thereof to the gate terminal 181 of the second transistor 153. As a result, a high growth rate of the output signals is achieved.

With the above in view, and unlike any other designs, the structure presented in FIG. 2a ensures substantial widening of the dynamic range of the signal transmission single-supply apparatuses, concurrently providing high growth rate of the output signal, thus achieving the claimed technical result.

Proceeding to the description of the output current setter 155 presented in a general way in FIG. 2a, it is understood that it can be implemented in a variety of fashions. The schematic of one of those possible implementations of the output current setter 155 for the current stabilizer 105 in the proposed apparatus is shown in FIG. 6. It operates as follows.

As power voltage E is applied to the first terminal 171 of the output current setter 155, a direct current starts flowing through connected in series resistors 605 and 613 of the output current setter 155, the value of the current being

$${I}_{3} = E / ( {R}_{605} + {R}_{613} )$$

where R₆₀₅ and R₆₁₃—rated values of resistance of the first, 605, and second, 613, resistors of the output current setter 155, respectively.

At the second terminal 173 of the output current setter 155, as a consequence of that, voltage U₀ appears which is equal in value to the voltage drop created by the current I₃ across the second resistor 613 of the output current setter 155:

$${U}_{0} = E * {R}_{613} / ( {R}_{605} + {R}_{613} ) \qquad ( 14 )$$

Using the relation (10), it is obtained that flowing through the current stabilizer 105, with the output current setter 155 configured as shown in FIG. 6, will be stable direct current

$${I}_{0} = {U}_{0} / {R}_{m} = E * ( {R}_{613} / ( {R}_{605} + {R}_{613} ) ) / {R}_{m} \qquad ( 15 )$$

Selecting values E, R₆₀₅, R₆₁₃ and Rₘ as needed, the required value of Io can always be obtained. Accordingly, the output current setter 155 shown in FIG. 6 ensures performance of the current stabilizer of FIG. 2a and of the proposed apparatus altogether.

However, the dependence of the output voltage U₀ on the value of the power voltage E, which may be unstable, appears a disadvantage of the schematic of FIG. 6.

The schematic of another possible implementation of the current setter 155 for the current stabilizer 105 in the proposed apparatus which possesses advanced stability of the voltage Uo is presented in FIG. 7. It operates in the following way. When power voltage E is applied to the first terminal 171 of the output current setter 155, direct current La starts flowing through connected in series the FET 703 and the first, 707, and second, 713, setter resistors of the output current setter 155. In accordance with the FET properties, if drain-source voltage between the terminals 741 (drain terminal) and 743 (source terminal) of the FET 703 of the output current setter 155 exceeds the cut-off voltage (a characteristic parameter of a FET), then the current 14 between those terminals does not depend on the drain-source voltage and is determined only by properties of the FET and the gate-source voltage. The gate-source voltage between the terminals 731 and 743 of the FET 703 of the output current setter 155 is determined by a voltage drop across the first resistor 707 and equals to I₄*R₇₀₇. At the same time, the voltage drop

$${U}_{0} = {I}_{4} * {R}_{713} \qquad ( 16 )$$

is formed across the second resistor 713, where R₇₀₇ and R₇₁₃ are the rated values of resistance of the first and second resistors of the output current setter 155.

This voltage U₀, independent of the power voltage E, comes to the second terminal 173 of the output current setter 155. Using the relation (10), it is obtained that flowing through the current stabilizer 105, with the output current setter 155 configured as shown in FIG. 7, will be stable direct current

$${I}_{0} = {U}_{0} / {R}_{m} = {I}_{4} * {R}_{713} / {R}_{m} \qquad ( 17 )$$

Selecting the FET 703 and values of R₇₁₃ and Rₘ as needed, the required value of lo can always be obtained. Hence, the output current setter 155 shown in FIG. 7 ensures operability of the current stabilizer 105 and of the proposed apparatus altogether, the stability of the voltage U₀ and, accordingly, of the current I₀ of the current stabilizer 105), being substantially higher than in the schematic in FIG. 6 because the current I₃ of the FET 703 is much more stable than the power voltage E.

The schematic of the third possible embodiment of the output current setter 155 for the current stabilizer 105 in the proposed apparatus which possesses advanced stability of the voltage U₀ is presented in FIG. 8 and operates in the following way.

When power voltage E is applied to the first terminal 171 of the output current setter 155, direct current starts flowing through connected in series resistors-first, second and third 805, 807, and 813—of the output current setter 155. Flowing through the first setter resistor 805 is the direct current Is equal to

$${I}_{5} = ( E - {V}_{d} ) / {R}_{805} \qquad ( 18 )$$

where V_{d} is the voltage between the terminals 835 and 837 of the reference voltage source terminal 801 of the output current setter 155, and flowing through the second, 807, and third, 813, setter resistors is current

$${I}_{6} = {V}_{d} / ( {R}_{807} + {R}_{813} ) . \qquad ( 19 )$$

In response to that, voltage U₀ appears at the first terminal 843 of the third resistor 813 and, accordingly, at the second terminal 173 of the output current setter 155. U₀ does not depend on the power voltage E and is equal in value to the I₃—caused voltage drop across the third resistor 813 of the output current setter 155:

$${U}_{0} = {V}_{d} * {R}_{813} / ( {R}_{807} + {R}_{813} ) . \qquad ( 20 ) ;$$

Using the relation (10), it is obtained that flowing through the current stabilizer 105, with the output current setter 155 configured as shown in FIG. 8, will be direct current

$${I}_{0} = {U}_{0} / {R}_{m} = {V}_{d} * ( {R}_{813} / ( {R}_{807} + {R}_{813} ) ) / {R}_{m} . \qquad ( 21 )$$

Selecting values of E, R₈₁₃, R₈₀₇ and Rₘ as needed, the required value of I₀ can always be ensured. Hence, the output voltage setter 155 shown in FIG. 8 allows for the operability of the current stabilizer 105 and of the proposed apparatus altogether. The stability of the voltage U₀ and, accordingly, of the current stabilizer 105 current I₀, is substantially higher than that in the schematic in FIG. 6 because the voltage V_{d} between the terminals 835 and 837 of the reference voltage source 801 is much more stable than the power voltage B.

In view of the above, attaining the claimed technical result is illustrated by charts in FIGS. 9a-9f. Shown there are: the input undistorted signal 901 looking like a sinewave with the minimum value thereof at zero; the real amplitude response 902 of prior art designs which is substantially nonlinear at the initial area resulting in the distortion of “near-zero” signals; the amplitude response 903 of the proposed design, which is close to linear, thus contributing to decreasing distortion of “near-zero” signals; the output signal 904 in the prior art designs looking distorted due to the flattening of the sinewave in the range of small magnitudes; and the output signal 905 in the proposed design having substantially lower level of distortion in the range of small magnitudes, whereby the dynamic range of the single-supply signal transmission apparatuses can be broadened.

Also absent, due to using the class A amplification mode, are non-linear distortions which are specific for prior art, including the prototype, where the AB amplification mode is employed.

The above-discussed embodiments do not limit the scope of the proposed and claimed apparatus. It is understood that various embodiments relating to the hardware of the particular elements are feasible. For example, the above-discussed first voltage divider formed by the resistors 443 and 445, the second voltage divider formed by the resistors 549 and 547, the third voltage divider formed by the resistors 605 and 613, the fourth voltage divider formed by the resistors 707 and 713, the fifth voltage divider formed by the resistors 805, 807 and 813—from FIGS. 4, 5, 6, 7, and 8, respectively, as well as the sixth voltage divider formed by the resistors 443 and 545 (FIG. 5), can each be a resistance divider or can be made as a divider comprising transistors connected in series, or in any other fashion providing required voltage in a midpoint of the divider. Furthermore, any of the above-mentioned resistors can be made as an element having preferably active resistance. For example, a semiconductor layer isolated of other elements can represent a resistor in an integral circuit.

Similarly, OA ICs, such as OPA 189, OPA 365 and many others, can be used as the OA 101 and 151 (in FIG. 2a). Critical parameters of the ICs are: OPEN-LOOP GAIN (at the load of 10 kiloohm) of no less than 100 dB; gain-bandwidth product of no less than 1 MHz; acceptable minimal input signal must be lower than a neutral bus potential by, for example, 0.1 V, whereas the zero offset must be many fold less than the minimal output voltage Uₒᵤₜ. FET, such as BSS83, RU1C001UN, FDN028N20, and other FET, can be used as transistors 103, 153. In such a case, the first, control, electrode is the gate, the second electrode is the drain, and the third electrode is the source. Critical parameters of the transistor 103 are: drain current Io is no less than 100 mA, voltage gate-source must exceed the minimal output voltage of the OA 101. For the transistor 153, R_{DC(on)} must be no more than several hundred milliohms. For both transistors, parasitic capacitances must be minimal. Also, other types of transistors, such as bipolar, can be used. In such a case, the first, control, electrode is base, the second electrode is collector, and the third one is emitter. In a function of the transistor 703 (in FIG. 7), only FET, such as BSS83,RU1C001UN, etc., can be used. The key factor when selecting a FET by its parameters is that the drain-source voltage must be larger than the cutoff voltage. In a function of the current setter 155 (in FIG. 2a), beside structures presented in FIGS. 6-8, other schematics capable of creating stable voltage U₀, setting the direct current lo of the current stabilizer 105, can be used, Portions of some elements discussed above can differ, overlap, or completely coincide with portions of other elements unless specifically mentioned otherwise. Also, unless specifically mentioned otherwise, portions of some elements can be situated in various portions of other elements. Where noted that an element is “connected” to/with another element, this is understood to mean that that element can be “directly connected” with the other element or “electrically connected” with the other element via a third element. For example, a decoupling resistor or a matching stage can be put between OA 101 and transistor 103. Same relates to the connection of the second OA 151 and second transistor 153 in the current stabilizer 105. Also, unless mentioned otherwise, “include” and derivatives thereof, such as “including”, are understood to mean the presence of the elements mentioned, rather than the absence of any other elements.

The claimed apparatus can be made as an integral circuit, or an integral circuit assembly, or a micro board with terminals 107, 109, 127, 135. Also, the claimed apparatus can be made as an integral circuit, or an integral circuit assembly, or a micro board with terminals 107, 109, 119, 127, 129, 135, 167, to which an integral circuit, or an integral circuit assembly, or a micro board with terminals 121, 123, 125, 171, 173, 177 is connected. As well, the claimed apparatus can be made as an OA integral circuit, or an integral circuit assembly, or a micro board with terminals 111, 113, 115, 117, 119, 131, 133, 167, to which an integral circuit, or a integral circuit assembly, or a micro board with terminals 121, 123, 125, 137, 139, 141, 171, 173, 177 is connected. Equally possible are other options of decomposing the apparatus, and the claimed apparatus can as well be a portion of other structures or other IC.

### Experimental Results

To corroborate the attainability of the claimed technical result, breadboarding of two versions of the apparatus according to the schematic of FIG. 2a (a voltage repeater mode) was carried out. In one of the breadboard circuits, integral circuit s OPA 2189 were used as the OAs 101 and 151. In the other-integral circuit s OPA 365, For both circuits, transistors RU1C001UN and NTNS3C68NZ were used as transistors 103 and 153, respectively. The below table illustrates the results of breadboarding.

| | |
|---|---|
| Breadboarding | Breadboarding |
| circuit 1: | circuit 2: |
| OPA 2189 as | OPA 365 as |
| OA 101, 151 | OA 101, 151 |

| | | | | |
|---|---|---|---|---|
| Power supply voltage | 5.1 | V | 5.0 | V |

| | | |
|---|---|---|
| Minimal non-distorted | Less 1 mV | Less 1 mV |
| output voltage | | |

| | | | | |
|---|---|---|---|---|
| Maximal output voltage | 3.75 | V | 3.7 | V |
| Growth rate | 13 | V/μs | 26 | V/μs |

It follows from the table that the technical result achieved by the claimed invention is definitely lies in the substantial widening of the dynamic range of the apparatus with single supply, as compared with the prior art, with, at the same time, ensuring high growth rate of the output signal.

Shown in FIG. 10 are oscillograms of the input test voltage (chart 1001) and output voltage (chart 1002) for the breadboarding circuit 1. The saw-tooth shape of the input test voltage was chosen for better demonstrativeness. The input voltage Uᵢₙ comes over channel K; of the oscillograph, the scale being 10 mV per square. The output voltage Uₒᵤₜ was indicated at channel K₄ of the oscillograph, the scale being the same. It follows from the oscillograms that distortions of the minimal output signal (saw rounding) is less than 1 mV which corroborates that the claimed technical result was achieved.

The claimed apparatus made according to the above recommendations and drawings can be very well repeated.

The claimed invention has been described based on what is currently considered feasible implementation of various embodiments thereof. It should be noted, however, that it is not limited thereby. On the contrary, it is intended for operating in various modifications and equivalent implementations keeping with the ideas, spirit and scope of the below claims. For example, the apparatus with widened dynamic range and single-supply operation can be used as a signal buffer for high-sensitive high-impedance sensor, in input stages of ADC and output stages of DAC (including integral circuit versions thereof), small signal detectors, and in many other applications. Accordingly, the description and drawings are illustrative only and do not limit implementability of the invention. The claimed technical design is defined by the below claims.

1. A single-supply apparatus (100) for signal transmission, comprising a first operational amplifier (101), a second operational amplifier (151), a first transistor (103), a second transistor (153), and a resistor (157), an output 119 of the first operational amplifier (101) being connected to a terminal (121) of a first electrode of the first transistor (103), a noninverting input (115) of the first operational amplifier (101) being connected to a terminal (109) of the apparatus (100) intended for receiving an input signal, an output (165) of the second operational amplifier (151) being connected to a terminal (181) of a first electrode of the second transistor (153), a terminal (193) of a third electrode of the second transistor (153) being connected to an inverting input (169) of the second operational amplifier (151) and to a terminal (187) of the resistor (157), wherein the apparatus (100) is further provided with a feedback circuit (143) and an output current setter (155), a junction point of a terminal (123) of a third electrode of the first transistor (103) and a terminal (191) of a second electrode of the second transistor (153) is connected to a first terminal (137) of the feedback circuit (143) intended for connecting to a load, a second terminal (139) of the feedback circuit (143) is connected to an inverting input (117) of the first operational amplifier (101), and an output (173) of the output current setter (155) is connected to a non-inverting input (167) of the second operational amplifier (151), to thereby ensure that the dynamic range of the apparatus is widened and the growth rate of the output signal is high.

2. The apparatus according to claim 1, wherein the feedback circuit (143) is made as a wire.

3. The apparatus according to claim 1, wherein the feedback circuit (143) comprises a first voltage divider (443; 445), the first element (443) of the voltage divider (443; 445) being connected between the first, (137), and the second, (139), terminals of the feedback circuit (143), the second element (445) of the voltage divider (443; 445) being connected between the second, (139), and a third, (141), terminals of the feedback circuit (143).

4. The apparatus according to claim 1, wherein it further comprises a second voltage divider (547; 549) placed between the first terminal (109) of the apparatus and the non-inverting input (115) of the first operational amplifier (101), and also comprises an element (545) having preferably active resistance and connected between a second input (118) of the apparatus and the inverting input (117) of the first operational amplifier (101), the feedback circuit (143) comprising an element (443) having preferably active resistance, connected between the first (137) and the second (139) terminals of the feedback circuit (143).

5. The apparatus according to claim 1, wherein the first (103) and the second (153) transistors are FET, the first electrodes of the first and second transistors with the terminals (121) and (181), respectively, are gates, and the second electrodes of the first and second transistors with the terminals (125) and (191), respectively, are drains.

6. The apparatus according to claim 1, wherein the first (103) and the second (153) transistors are bipolar, the first electrodes of the first and second transistors with the terminals (121) and (181), respectively, are bases, and the second electrodes of the first and second transistors with the terminals (125) and (191), respectively, are collectors.

7. The apparatus according to claim 1, wherein the output current setter (155) comprises a third voltage divider (605; 613), a first terminal (621) of the first element (605) of the third voltage divider (605; 613) being connected to a first terminal (171) of the output current setter (155), a junction point of the first (605) and the second (613) elements of the third voltage divider (605; 613) being connected to the second terminal (173) of the output current setter (155), and a second terminal (629) of the second element (613) of the third voltage divider (605; 613) being connected to a third terminal (177) of the output current setter (155).

8. The apparatus according to claim 1, wherein the output current setter (155) comprises a FET (703) and a fourth voltage divider (707; 713), a terminal (741) of the FET (703) drain being connected to a first terminal (171) of the output current setter (155), a terminal (743) of the FET (703) source being connected to a first terminal (737) of the first element (707) of the fourth voltage divider (707; 713), a terminal (731) of the FET (703) gate being connected to a junction point of the first (707) and the second (713) elements of the fourth voltage divider (707; 713) and to the second terminal (173) of the output current setter (155), and a second terminal (727) of the second element (713) of the fourth voltage divider (707; 713) being connected to a third terminal (177) of the output current setter (155).

9. The apparatus according to claim 1, wherein the output current setter (155) comprises a reference voltage source (801) and a fifth voltage divider (805; 807; 813), a first terminal (831) of the first element (805) of the fifth voltage divider (805; 807; 813) being connected to a first terminal (171) of the output current setter (155), a second terminal (833) of the first element (805) of the fifth voltage divider (805; 807; 813) being connected to a first terminal (835) of the reference voltage source (801), and to a first terminal (839) of the second element (807) of the fifth voltage divider (805; 807; 813), a second terminal (841) of the second element (807) of the fifth voltage divider (805; 807; 813) being connected to the second terminal (173) of the output current setter (155) and to a first terminal (843) of the third element (813) of the fifth voltage divider (805; 807; 813), a second terminal (845) of the third element (813) of the fifth voltage divider (805; 807; 813) being connected to a third terminal (177) of the output current setter (155) and to a second terminal (837) of the reference voltage source (801).

10. A single supply integral circuit (IC) (200) for signal transmission, comprising a first operational amplifier (101), a second operational amplifier (151), a first transistor (103), a second transistor (153), and a resistor (157), an output (119) of the first operational amplifier (101) being connected to a terminal (121) of a first electrode of the first transistor (103), a non-inverting input (115) of the first operational amplifier (101) being connected to a terminal (109) of the integral circuit (200) intended for receiving an input signal, an output (165) of the second operational amplifier (151) being connected to a terminal (181) of a first electrode of the second transistor (153), a terminal (193) of a third electrode of the second transistor (153) being connected to an inverting input (169) of the second operational amplifier (151) and to a terminal (187) of the resistor (157), wherein a terminal (123) of a third electrode of the first transistor (103) in the integral circuit (200) is connected to a terminal (191) of a second electrode of the second transistor (153), the junction point thereof is connected to a terminal (135) reserved for connecting a load, and the terminal (135) is also reserved for connecting to a first terminal of an outside feedback circuit (143), to thereby ensure that the dynamic range of the IC is widened and the growth rate of the output signal is high.

11. (canceled)

12. The integral circuit according to claim 10, wherein it is provided with an additional terminal (118) connected to an inverting input (117) of the first operational amplifier (101) and reserved for connecting to a second terminal of an outside feedback circuit (143).

13. The integral circuit according to claim 12, wherein the additional terminal (118) is reserved for receiving a second input signal.

14. The integral circuit according to claim 10, wherein it is further provided with an the output current setter (155) comprising a third voltage divider (605; 613), a first terminal (621) of the first element (605) of the third voltage divider (605; 613) being connected to a first terminal (171) of the output current setter (155), a junction point of the first (605) and the second (613) elements of the third voltage divider (605; 613) being connected to the second terminal (173) of the output current setter (155), and a second terminal (629) of the second element (613) of the third voltage divider (605; 613) being connected to a third terminal (177) of the output current setter (155).

15. The integral circuit according to claim 10, wherein it is further provided with an output current setter (155) comprising a FET (703) and a fourth voltage divider (707; 713), a terminal (741) of the FET (703) drain being connected to a first terminal (171) of the output current setter (155), a terminal (743) of the FET (703) source being connected to a first terminal (737) of the first element (707) of the fourth voltage divider (707; 713), a terminal (731) of the FET (703) gate being connected to a junction point of the first (707) and the second (713) elements of the fourth voltage divider (707; 713), and to the second terminal (173) of the output current setter (155), and a second terminal (727) of the second element (713) of the fourth voltage divider (707; 713), being connected to a third terminal (177) of the output current setter (155), and an output (173) of the output current setter (155) is connected to a non-inverting input (167) of the second operational amplifier (151).

16. The integral circuit according to claim 10, wherein it is further provided with an output current setter (155) comprising a reference voltage source (801) and a fifth voltage divider (805, 807, 813), a first terminal (831) of the first element (805) of the fifth voltage divider (805; 807; 813) being connected to a first terminal (171) of the output current setter (155), a second terminal (833) of the first element (805) of the fifth voltage divider (805; 807; 813) being connected to a first terminal (835) of the reference voltage source (801), a first terminal (839) of the second element (807) of the fifth voltage divider (805; 807; 813) being connected to the second terminal (833) of the first element (805) of the fifth voltage divider (805; 807; 813), a second terminal (841) of the second element (807) of the fifth voltage divider (805; 807; 813) being connected to the second terminal (173) of the output current setter (155) and to a first terminal (843) of the third element (813) of the fifth voltage divider (805; 807; 813), a second terminal (845) of the third element (813) of the fifth voltage divider (805; 807; 813) being connected to a third terminal (177) of the output current setter (155) and to a second terminal (837) of the reference voltage source (801), and a second terminal (173) of the output current setter (155) is connected to a non-inverting input (167) of the second operational amplifier (151).

17. The integral circuit according to claim 10, wherein it is provided with an additional terminal (163) connected to an inverting input (167) of the second operational amplifier (151) and reserved for connecting to an outside current setter.
